(19) United States
(12) Patent Application Publication
(10) Pub. No.: US 2020/0027771 A1
(43) Pub. Date: Jan. 23, 2020

(54) TEMPORARY-FIXING SUBSTRATE AND METHOD FOR TEMPORARILY FIXING ELECTRONIC COMPONENT

(71) Applicant: NGK INSULATORS, LTD., Nagoya-city (JP)

(72) Inventors: Masaru NOMURA, Owariasahi-City (JP); Sugio MIYAZAWA, Kasugai-City (JP)

(21) Appl. No.: 16/585,526

(22) Filed: Sep. 27, 2019

Related U.S. Application Data
(63) Continuation of application No. PCT/JP2018/002371, filed on Jan. 26, 2018.

(30) Foreign Application Priority Data
Mar. 30, 2017 (JP) 2017-066812

(51) Int. Cl. H01L 21/683

(52) U.S. Cl. CPC H01L 21/6835; H01L 2221/68318

(57) ABSTRACT

A temporary-fixing substrate includes a fixing face for adhering and temporary fixing a plurality of electronic parts by a resin mold on the fixing face and a bottom face on the opposite side of the fixing face. The temporary-fixing substrate is warped so that the fixing face is of a convex shape curved upwardly from the temporary-fixing substrate viewed in a cross section of the temporary-fixing substrate. The following formula (1) is satisfied, provided that W is assigned to a width of the fixing face viewed in the cross section of the temporary-fixing substrate, and provided that W_{3/4} is assigned to a width of a region in which heights of the fixing face with respect to a reference plane of warping of the temporary-fixing substrate are ¾ or larger of the maximum value of the heights of the fixing face with respect to the reference plane.

0.45≤W_{3/4}/W≤0.55 (1)

### CROSS-REFERENCE TO RELATED APPLICATIONS

This application is a continuation application of PCT/JP2018/002371, filed Jan. 26, 2018, which claims priority to Japanese Application No. 20170066812, filed Mar. 30, 2017, the entire contents all of which are incorporated hereby by reference.

### TECHNICAL FIELD

The present invention relates to a temporary-fixing substrate including a fixing face for adhering and temporary-fixing electronic parts with a resin mold and a bottom face on the opposite side of the fixing face.

### BACKGROUND ARTS

It is known a method of adhering and fixing electronic parts made of silicon or the like on a supporting body made of a glass or ceramic (Patent documents 1, 2 and 3). According to such related arts, electronic parts are adhered to a supporting body with a thermal curable resin and then cooled to obtain a bonded body. In this case, it is tried to adjust the warpage of the supporting body to reduce the warpage of the bonded body. Further, the warpage of the supporting body is adjusted by changing a method of polishing or removing the processing denatured layer.

Further, according to patent document 4, it is disclosed the following. That is, when a light-emitting diode is mounted on a surface of a sapphire substrate, first and second main faces of the sapphire substrate are polished by lapping and only the first main face is subjected to precise polishing by CMP or the like.

### RELATED TECHNICAL DOCUMENTS

### Patent Documents

(Patent document 1) Japanese Patent publication No. 2011-023438A
(Patent document 2) Japanese Patent publication No. 2010-058989A
(Patent document 3) Japanese Patent No. 5304112B
(Patent document 4) Japanese Patent publication No. 2016-139751A

### SUMMARY OF THE INVENTION

The present inventors researched to adhere many electronic parts on a temporary-fixing substrate made of a glass or ceramic and to temporary fix the electronic parts with a resin mold. During the process, it has been researched the application of various kinds of supporting bodies described in related arts.

However, in the case that a plurality of the electronic parts is adhered and then temporary-fixed on the temporary-fixing substrate with the resin mold, unique problems are proved to be provided. That is, after the electronic parts are adhered onto the temporary-fixing substrate, liquid resin mold agent is flown and then solidified by heating, so that the electronic parts are fixed in the resin mold. Then, ultraviolet light is irradiated from the side of the temporary-fixing substrate to separate the resin mold and temporary-fixing substrate, so that the electronic parts are separated from the temporary-fixing substrate with the resin mold.

However, when the electronic parts are temporarily fixed in the resin mold, it may be generated the electronic parts with unstable temporary-fixation, resulting in reduction of the yield. That is, the liquid resin mold agent is flown onto the temporary-fixing substrate to supply the agent into spaces between the adjacent electronic parts, and the agent is heated and solidified as such. The fixation of the electronic parts positioned, for example, in a peripheral part or in a central part of the temporary-fixing substrate may be defective, so that it may not be possible to obtain uniform fixation state over the whole of the substrate. Thus, such local defective fixation on the temporary-fixing substrate results in the reduction of the yield which demands the solution.

An object of the present invention is, in fixing a plurality of electronic parts in a resin mold on a temporary-fixing substrate, to suppress local defects of the mold on the temporary-fixing substrate and to improve the yield.

The present invention provides a temporary-fixing substrate comprising a fixing face for temporary adhering and fixing a plurality of electronic parts by a resin mold on the fixing face and a bottom face on the opposite side of the fixing face;

wherein the temporary-fixing substrate is warped so that the fixing face is of a convex shape curved upwardly from the temporary-fixing substrate is a cross section of the temporary-fixing substrate; and

wherein the following formula (1) is satisfied,

provided that W is assigned to a width of the fixing face viewed in the cross section of the temporary-fixing face and provided that W_{3/4} is assigned to a width of a region in which heights of the fixing face with respect to a reference plane of warping of the temporary-fixing substrate are ¾ or larger of the maximum value of the heights of the fixing face with respect to the reference plane.

0.45≤W_{3/4}/W≤0.55 (1)

The present invention further provides a method of temporary-fixing electric parts, the method comprising the steps of:

preparing a temporary-fixing substrate comprising a fixing face for adhering and temporary-fixing a plurality of electronic parts by a resin mold on the fixing face and a bottom face on the opposite side of the fixing face, wherein the temporary-fixing substrate is warped so that the fixing face is of a convex shape curved upwardly from the temporary-fixing substrate is a cross section of the temporary-fixing substrate, and wherein the following formula (1) is satisfied, provided that W is assigned to a width of the fixing face viewed in the cross section of the temporary-fixing substrate and provided that W_{3/4} is assigned to a width of a region in which heights of the fixing face with respect to a reference plane of warping of the temporary-fixing substrate are ¾ or larger of the maximum value of the heights of said fixing face with respect to the reference plane; and

adhering and temporary-fixing the electronic parts on the fixing face of the temporary-fixing substrate with the resin mold.

0.45≤W_{3/4}/W≤0.55 (1)

The present inventors researched the cause of defection of a resin mold, in fixing a plurality of electronic parts on a temporary-fixing substrate with the resin mold, depending on the position in the temporary-fixing substrate. As a result, it is found that the defects of the mold tend to occur in a peripheral part or central part of the temporary-fixing substrate. Then, in the case that the defects of the mold is generated in the peripheral part of the temporary-fixing substrate, the defects of the mold is hardly generated in the central part, and in the case that the defect of the mold is generated in the central part of the temporary-fixing substrate, the defect of the mold is hardly generated in the peripheral part.

The present inventors researched such phenomenon and it was found that, when the electronic parts are adhered onto the temporary-fixing substrate and the liquid molding agent is flown thereon, the defect of filling of the molding agent tends to occur locally. It was then focused on the microscopic shape of fixing face (mounting face) of the temporary-fixing substrate. That is, a conventional temporary-fixing substrate is slightly warped in a convex shape toward the direction of the fixing face, and the convex shape is of substantially an arc. However, the shape of the fixing face of the temporary-fixing substrate in a cross section of the temporary-fixing substrate is made parabolic shape or near-parabolic shape (that is, the shape satisfying the formula (1) described above), so that the defects of the mold of the electronic parts on the temporary-fixing substrate is suppressed to improve the yield of the molding step. The present invention was thus made.

### BRIEF DESCRIPTIONS OF THE DRAWINGS

FIG. 1 is a cross sectional view showing the state that a temporary-fixing substrate 2 of an embodiment of the present invention is mounted onto a surface plate 1.

FIG. 2 is a plan view showing a fixing face of the temporary-fixing substrate 2.

FIG. 3 is a cross sectional view showing the state that a temporary-fixing substrate 12 of a comparative example is mounted on the surface plate 1.

FIG. 4(a) shows the state that an adhesive 3 is provided on the fixing face 2a of the temporary-fixing substrate 2, FIG. 4(b) shows the state that electronic parts 4 are adhered onto the fixing face 2a of the temporary-fixing substrate 2, and FIG. 4(c) shows the state that electronic parts 4 are temporarily fixed with a resin mold 6.

### EMBODIMENTS FOR CARRYING OUT THE INVENTION

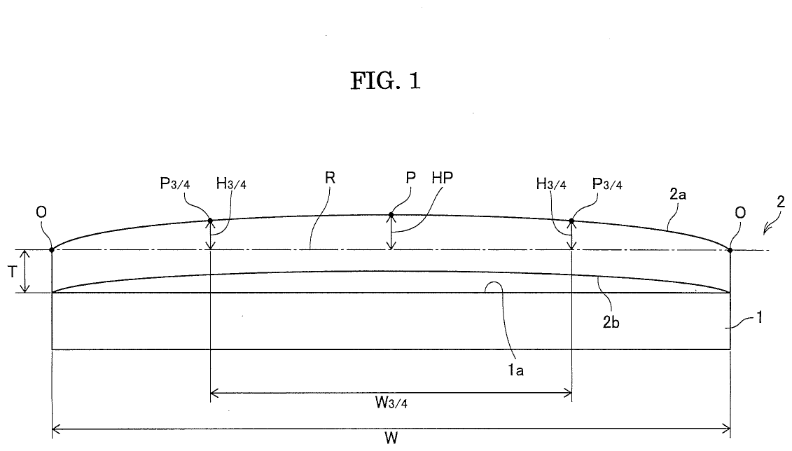

As shown in FIG. 1, a bottom face 2b of a temporary-fixing substrate 2 is mounted on a surface 1a of a surface plate 1. A fixing face 2a of the temporary-fixing face 2 is provided on the opposite side of the bottom face 2b. Here, T is assigned to a thickness of the temporary-fixing substrate 2, the temporary-fixing substrate 2 is slightly warped upwardly, and the fixing face 2a is slightly warped upwardly in a convex shape. However, in the drawings, the warpage is shown with exaggeration for the ease of understanding.

Here, according to the present invention, the temporary-fixing substrate 2 is warped so that the fixing face 2a is of a convex shape curved upwardly from the temporary-fixing substrate 2 viewed in a cross section of the temporary-fixing substrate 2, and the fixing face 2a satisfies the following formula (1).

0.45≤W_{3/4}/W≤0.55 (1)

It is provided that the temporary-fixing substrate 2 is mounted onto the surface 1a of a surface plate 1. The bottom face 2b of the temporary-fixing substrate contacts the surface 1a, so that the supporting substrate 2 is supported. At this stage, the temporary-fixing substrate is slightly warped upwardly in a convex shape. Here, W is assigned to a width of the fixing face 2a viewed in the cross section of the temporary-fixing substrate. Further, R is assigned to a reference plane of the warpage of the temporary-fixing substrate 2, provided that the reference plane passes through a point O at which a distance of the fixing face 2a of the temporary-fixing substrate 2 and the surface 1a of the surface plate 2 takes the minimum value, and the reference plane is parallel with the surface 1a of the surface plate 1.

It is then measured heights of the fixing face 2a with respect to the reference plane R. Here, O is assigned to a height of zero, P is assigned to a point at which the height takes the maximum value, and HP is assigned to the maximum value of the height. Further, P_{3/4} is assigned to a point at which the height of the fixing face 2a with respect to the reference plane R is ¾ (H_{3/4}) of the maximum value HP, and W_{3/4} is assigned to a width of a region in which the heights of the fixing face 2a with respect the reference plane are ¾ (H_{3/4}) of the maximum value HP or larger.

In this case, W_{3/4}/W is made 0.45 or higher and 0.55 or lower, and electronic parts are fixed on the temporary-fixing substrate with a resin mold, it is possible to suppress the mold defects depending on the position. Although the reason is not clear, it may be considered as follows. In the case that the fixing face is of parabolic shape, W_{3/4}/W is 0.50. The above formula means that the fixing face is of parabolic shape or near-parabolic shape. In the case that such shape is applied, when liquid molding agent is flown into spaces between the electronic parts on the temporary-fixing substrate, the molding agent is appropriately positioned over the whole surface of the fixing face to suppress the mold defect.

Here, in the case that W_{3/4}/W is lower than 0.45, many mold defects are generated in the central part of the fixing face of the temporary-fixing substrate. W_{3/4}/W is thus made 0.45 or higher and preferably 0.48 or higher. Further, in the case that W_{3/4}/W exceeds 0.55, many mold defects are generated in the peripheral part of the fixing face. W_{3/4}/W is thus made 0.55 or lower and more preferably 0.52 or lower. More preferably, the fixing face is of substantially parabolic shape.

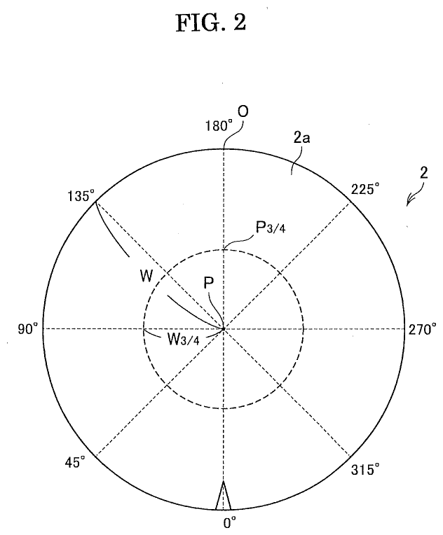

It will be described the method of measuring the heights of the fixing face with respect to the reference plane. As shown in FIG. 1, the temporary-fixing substrate is mounted on a surface plate 1. Then, as shown in FIG. 2, the fixing face 2a of the temporary-fixing substrate 2 is divided in eight directions. Then, the directions are decided per 45° rotation reference to notch as a reference point of 0° Then, the measurement is performed along four lines of “0°-180°”, “45°-225°”, “90°-270°”, and “135°-315°”. Specifically, the respective measurement points are set on each of the lines and in a pitch of 1 mm. The number of the measurement points is 1200 points (300 points×4 lines) per the single substrate, for example, in the case of the substrate of 12 inches.

It is used a laser displacement meter (“LK-H027K” supplied by KEYENCE) for measuring the heights of the fixing face with respect to the reference plane. Then, as described referring to FIGS. 1 and 2, provided that HP is assigned to the maximum value of the heights, it is measured a number of the measurement points at which the heights are ¾×P or higher. Then, W_{3/4}/W is assigned to (number of the measurement points at which the heights are ¾×P or higher)/(number of all the measurement points).

Further, in the case that nine or less of the measurement points, at which the heights are ¾×P or higher, are continuous, such points are deemed as abnormal measurement points and not included in “number of measurement points at which the heights are ¾×P or higher”.

According to the present invention, the temporary-fixing substrate is warped so that the fixing face of the temporary-fixing substrate is of a shape of a convex toward a direction on the opposite side of the bottom face in the cross section. Here, the convex shape means that a line segment connecting optional two points on an outer profile line of the fixing face is positioned inside of the outer profile line of the fixing face of the temporary-fixing substrate. Thus, it is excluded the cases that a recess or a flat surface is provided in the fixing face.

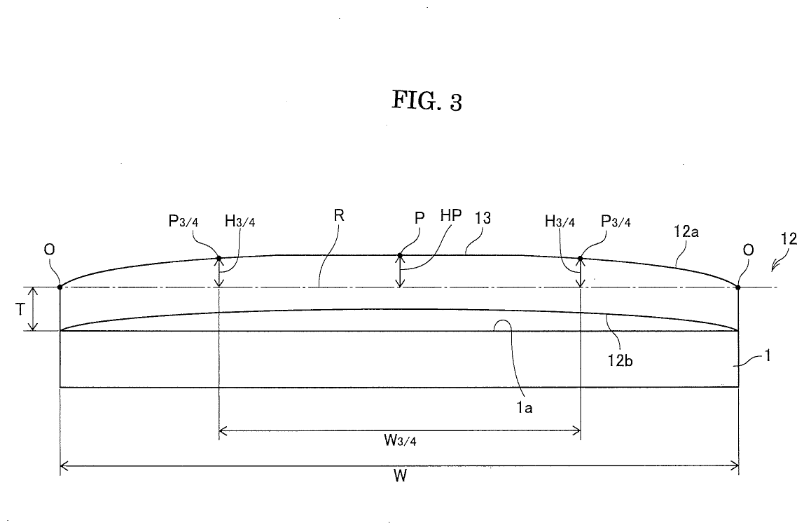

For example, according to a temporary-fixing substrate 12 shown in FIG. 3, a flat face 13 is provided in a central part of a fixing face 12a. 12b represents a bottom face. In this case, the line segment connecting the outer profile line of the fixing face may not be positioned in the inside of the temporary-fixing substrate and may be positioned in a flat surface 13. It is thus not said that the fixing face is of the convex shape curved upwardly. In this case, the effect of the present invention is not obtained even if W_{3/4}/W is 0.45 to 0.55. Further, it also applies in the case that the recessed surface is provided in the fixing face.

The ratio (HP/T) of the maximum value of the heights of the fixing face of the temporary-fixing substrate with respect to the thickness may preferably be 0.1 to 0.5 and more preferably be 0.125 to 0.25. Further, the thickness T may preferably be 0.3 mm to 3 mm and more preferably be 0.5 to 1.5 mm.

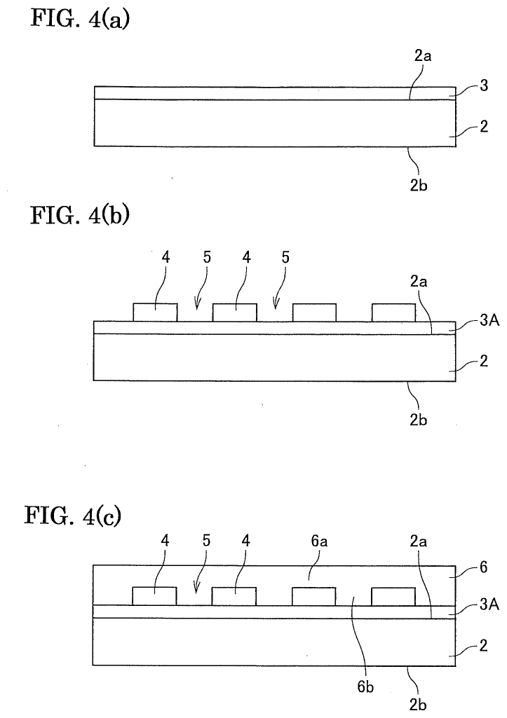

It will be described the process of temporarily fixing electronic parts on the temporary-fixing substrate. First, as shown in FIG. 4(a), an adhesive layer 3 is provided on the fixing face 2a of the temporary-fixing substrate 2.

Such adhesive includes a double-sided tape or a hot-melt-based adhesive. Further, as the method of providing the adhesive layer on the temporary-fixing substrate, it may be applied various methods including roll application, spray application, screen printing, spin coating and the like.

Then, as shown in FIG. 4(b), many electronic parts 4 are mounted on the temporary-fixing substrate 2 and the adhesive layer is solidified to form an adhesive layer 3A. The solidifying step is carried out depending on the nature of the adhesive and includes heating or irradiation of ultraviolet light.

Then, the liquid resin mold is flown and then solidified. By this, as shown in FIG. 4(c), the electronic parts 4 are fixed in the resin mold 6. Further, 6b represents a resin filling spaces 5 between the electronic parts and 6a represents a resin covering the electronic parts.

The molding resin used in the present invention includes epoxy resin, polyimide resin, polyurethane resin, urethane resin and the like.

The electronic parts and molding resin are then separated from the temporary-fixing substrate. The method of separation is not limited. Preferably, ultraviolet light is irradiated from the side of the bottom face 2b of the temporary-fixing substrate to separate the electronic parts and resin mold.

The material of the temporary-fixing substrate is not particularly limited and may preferably has mechanical strength and resistance against chemicals. According to a preferred embodiment, the temporary-fixing substrate is composed of alumina, silicon nitride, aluminum nitride or silicon oxide. The densities of the materials can be made high and the resistance against chemicals is high.

According to a preferred embodiment, the material of the temporary-fixing substrate is translucent alumina. In this case, preferably, 100 ppm more and 300 ppm or less of magnesium oxide is added to high-purity alumina powder having a purity of 99.9 percent or higher (preferably 99.95 percent or higher). Such high-purity alumina powder includes high-purity alumina powder produced by Taimei Chemical Industries Corporation. Further, the purity and average grain size of the magnesium oxide powder may preferably be 99.9 percent or higher and 50 μm or smaller, respectively.

According to a preferred embodiment, to the alumina powder, 200 to 800 mass ppm of zirconia (ZrO₂), and 10 to 30 mass ppm of yttria (Y₂O₃) are added as sintering aids.

The method of molding the temporary-fixing substrate is not particularly limited, and may be an optional process such as doctor blade, extrusion, gel cast molding or the like. Most preferably, the temporary-fixing substrate is produced utilizing gel cast molding.

According to a preferred embodiment, slurry containing ceramic powder, dispersing agent and gelling agent is cast into a mold, and the slurry is then gelled to obtain a molded body. During the gel cast molding, a releasing agent is applied onto mold parts, the mold parts are constructed and the slurry is injected. Then, the gel is solidified in the mold to obtain the molded body, which is then released from the mold. The mold is then washed.

Next, the gel molded body is dried, preferably, calcined in air, and then sintered in hydrogen. The sintering temperature in this sintering process is preferably in a range of 1700 to 1900° C., and more preferably in a range of 1750 to 1850° C. in terms of densification of the sintered body.

After generating the fully-dense sintered body in the sintering process, further an annealing treatment may be additionally performed, which can control or correct the warpage of the substrate. From the viewpoint of promoting the discharge of the sintering aids while preventing deformation and occurrence of abnormal grain growth, the annealing temperature is preferably within a range of the maximum temperature in the sintering ±100° C., in which the maximum temperature is more preferably 1900° C. or lower. The annealing time period is preferably in a range of 1 to 6 hours.

### EXAMPLES

It was produced the temporary-fixing substrate having the shape shown in FIGS. 1 and 3.

Specifically, it was produced slurry by mixing the following components.

### (Powdery Raw Material)

α-alumina powder having a specific surface area of 3.5 to 4.5 m²/g and an average primary particle size of 0.35 to 0.45 μm

| | 100 weight parts | |
|---|---|---|
| MgO (magnesia) | 0.025 | weight parts |
| ZrO₂(zirconia) | 0.040 | weight parts |
| Y₂O₃ | 0.0015 | weight parts |
| (Dispersing medium) | | |
| Dimethyl glutarate | 27 | weight parts |
| Ethylene glycol | 0.3 | weight parts |
| (Gelling agent) | | |
| MDI resin | 4 | weight parts |
| (Dispersing agent) | | |
| High molecular surfactant | 3 | weight parts |
| (Solvent) | | |
| N,N-dimethyl amino hexanol | 0.1 | weight parts |

The slurry was injected into a mold of aluminum alloy at room temperature and then stood for 1 hour at room temperature. The slurry was then stood for 40° C. for 30 minutes to proceed the solidification and then released from the mold. Further, it was stood at room temperature for 2 hours and then at 90° C. for 2 hours to obtain a plate-shaped powdery molded body.

The thus obtained powdery molded body was calcined (preliminary sintering) in atmosphere at 1100° C., and sintered in atmosphere of hydrogen nitrogen in a ratio of 3:1 at 1750° C. Thereafter, annealing treatment was performed under the same condition to obtain a blank substrate.

The thus produced blank substrate was subjected to high-precision polishing treatment. First, the shape was adjusted by double-sided lapping with green carbon, and the double-sided lapping with diamond slurry was then performed. The grain size of the diamond was made 3 μm. Finally, only one of the surfaces was subjected to CMP processing with SiO₂ abrasives and diamond abrasives and cleaning to obtain a temporary-fixing substrate of 12 inches.

However, the shape of the fixing face of the temporary-fixing substrate viewed in the cross section was changed as shown in table 1. Particularly, according to comparative example 3, it was provided a flat face having a width of 50 mm, and according to comparative example 4, it was provided a recess having a width of 50 mm and a depth of 0.1 mm.

Further, the shape of the fixing face of the temporary-fixing substrate was controlled by adjusting the processing conditions of CMP of the one of the surfaces.

Adhesive (UV separation tape, “SELFA-SE” (supplied by SEKISUI CHEMICAL CO., LTD.) was then applied on the temporary-fixing substrate, and 7500 counts of electronic parts each having dimensions of 2 mm×2 mm were regularly positioned. It was then heated at 200° C. to solidify the adhesive. Mold resin (“R4212-2C” (supplied by Nagase ChemteX Corporation) was then flown and heated for the solidification so that the electronic parts were fixed with the resin mold. It was finally observed whether the state of the mold was good or bad to calculate the yield of the molding step. The results were shown in table 1.

TABLE 1

| | | Cross sectional shape of | Yield |
|---|---|---|---|
| | W_{3/4}/W | Mounting face | (%) |
| Example 1 | 0.45 | Convex figure | 99.5 |
| | | (Parabolic shape) | |
| Example 2 | 0.50 | Convex figure | 99.7 |
| | | (Parabolic shape) | |
| Example 3 | 0.55 | Convex figure | 99.4 |
| | | (Parabolic shape) | |
| Com. Ex. 1 | 0.43 | Convex figure | 96.0 |
| Com. Ex. 2 | 0.57 | Convex figure | 95.0 |
| Com. Ex. 3 | 0.50 | including a flat surface | 93.0 |
| Com. Ex. 4 | 0.50 | Including a recess | 90.0 |

According to the inventive examples 1 to 3, it was obtained a high yield in the molding step.

According to comparative example 1, although the shape of the fixing face is a convex shape curved upwardly, W_{3/4}/W is as low as 0.43. It is generated mold defects in the central part of the fixing face to reduce the yield.

According to comparative example 2, although the shape of the fixing face is a convex shape curved upwardly, W_{3/4}/W is as high as 0.57. It is thus generated mold defects in the peripheral part of the fixing face to reduce the yield.

It was provided a flat surface in the central part of the fixing face according to the comparative example 3, and it was provided a recess in the central part of the fixing face according to the comparative example 4. Both of the yields are thereby reduced.

1. A temporary-fixing substrate comprising a fixing face for adhering and temporary fixing a plurality of electronic parts by a resin mold on said fixing face and a bottom face on the opposite side of said fixing face;
wherein said temporary-fixing substrate is warped so that said fixing face is of a convex shape curved upwardly from said temporary-fixing substrate viewed in a cross section of said temporary-fixing substrate; and
wherein the following formula (1) is satisfied,
provided that W is assigned to a width of said fixing face viewed in said cross section of said temporary-fixing substrate; and
provided that W_{3/4} is assigned to a width of a region in which heights of said fixing face with respect to a reference plane of warping of said temporary-fixing substrate are ¾ or larger of the maximum value of said heights of said fixing face with respect to said reference plane.
0.45≤W_{3/4}/W≤0.55 (1)

2. The temporary-fixing substrate of claim 1, wherein said fixing face has a substantially parabolic shape viewed in said cross section of said temporary-fixing substrate.

3. The temporary-fixing substrate of claim 1, comprising a glass, silicon or a ceramic.

4. The temporary-fixing substrate of claim 3, comprising translucent alumina.

5. A method of temporary-fixing electric parts, the method comprising the steps of:
preparing a temporary-fixing substrate comprising a fixing face for adhering and temporary fixing a plurality of electronic parts by a resin mold on said fixing face and a bottom face on the opposite side of said fixing face, wherein said temporary-fixing substrate is warped so that said fixing face is of a convex shape curved upwardly from said temporary-fixing substrate viewed in a cross section of said temporary-fixing substrate, and wherein the following formula (1) is satisfied, provided that W is assigned to a width of said fixing face viewed in said cross section of said temporary-fixing substrate, and provided that W_{3/4} is assigned to a width of a region in which heights of said fixing face with respect to a reference plane of warping of said temporary-fixing substrate are ¾ or larger of the maximum value of said heights of said fixing face with respect to said reference plane; and
adhering and temporary-fixing said electronic parts on said fixing face of said temporary-fixing substrate with said resin mold.
0.45≤W_{3/4}/W≤0.55 (1)

6. The method of claim 5, wherein said fixing face has a substantially parabolic shape viewed in said cross section of said temporary-fixing substrate.

7. The method of claim 5, wherein said temporary-fixing substrate comprises a glass, silicon or a ceramic.

8. The method of claim 7, wherein said temporary-fixing substrate comprises translucent alumina.
